(19) United States
(12) Patent Application Publication
(10) Pub. No.: US 2024/0416451 A1
(43) Pub. Date: Dec. 19, 2024

(54) MULTI-WAVELENGTH LASER FOR KILOWATT MATERIAL PROCESSING

(71) Applicant: Lumentum Operations LLC, San Jose, CA (US)

(72) Inventors: Richard D. FAULHABER, San Carlos, CA (US); Ning LIU, Morgan Hill, CA (US); Jeff GREGG, San Jose, CA (US); Guan SUN, San Jose, CA (US)

(21) Appl. No.: 18/463,936

(22) Filed: Sep. 8, 2023

Related U.S. Application Data
(60) Provisional application No. 63/507,912, filed on Jun. 13, 2023.

(51) Int. Cl. B23K 26/064; B23K 26/06; H01S 3/30

(52) U.S. Cl. CPC B23K 26/064; B23K 26/0604; H01S 3/302

(57) ABSTRACT

In some implementations, an optical system comprises a laser engine that comprises multiple laser sources configured to generate multiple lasers associated with different wavelengths and a signal combiner configured to combine the multiple lasers associated with the different wavelengths into broadband laser light. In some implementations, the optical system may further comprise a process cable configured to transmit the broadband laser light and a process head configured to receive the broadband laser light via the process cable such that the process head may focus the broadband laser light onto a workpiece.

### CROSS-REFERENCE TO RELATED APPLICATION

This Patent Application claims priority to U.S. Provisional Application No. 63/507,912, filed on Jun. 13, 2023, and entitled “MULTI-WAVELENGTH LASER FOR KILOWATT MATERIAL PROCESSING.” The disclosure of the prior Application is considered part of and is incorporated by reference into this Patent Application.

### TECHNICAL FIELD

The present disclosure relates generally to laser material processing and to a signal combiner that may combine lasers associated with different wavelengths in a manner that may preserve brightness and avoid nonlinear effects such as stimulated Raman scattering.

### BACKGROUND

In physics, the term scattering is generally used to describe various physical processes where moving particles or radiation in some form (e.g., light or sound) are forced to deviate from a straight trajectory by localized non-uniformities in a medium through which the particles or radiation pass. For example, Raman scattering (or the Raman effect) is the inelastic scattering of photons by matter, meaning that there is both an exchange of energy and a change in the direction that light is traveling. Raman scattering typically involves energy being gained by a molecule as incident photons from a visible laser are shifted to lower energy.

### SUMMARY

In some implementations, a laser engine includes multiple laser sources that are configured to generate multiple lasers associated with different wavelengths; and a signal combiner configured to: receive the multiple lasers associated with the different wavelengths; and combine the multiple lasers associated with the different wavelengths.

In some implementations, an optical system includes multiple laser sources that are configured to generate multiple lasers associated with different wavelengths; a signal combiner configured to combine the multiple lasers associated with the different wavelengths into broadband laser light; a process cable configured to transmit the broadband laser light; and a process head configured to receive the broadband laser light transmitted by the process cable and to focus the broadband laser light onto a workpiece.

In some implementations, a method for laser material processing includes generating, by an optical system, multiple lasers associated with different wavelengths using multiple laser sources; combining, by the optical system, the multiple lasers associated with the different wavelengths into broadband laser light using a signal combiner; transmitting, by the optical system, the broadband laser light through a process cable to a process head; and focusing, by the optical system, the broadband laser light onto a workpiece using the process head.

### BRIEF DESCRIPTION OF THE DRAWINGS

FIG. 1 is a diagram illustrating an example of light scattering.

FIG. 2 is a diagram illustrating an example industrial beam delivery system.

FIG. 3 is a diagram illustrating examples of single-wavelength fiber laser systems.

FIGS. 4A-4B are diagrams illustrating an example multi-wavelength fiber laser system.

FIG. 5 is a flowchart of an example process for laser material processing.

### DETAILED DESCRIPTION

The following detailed description of example implementations refers to the accompanying drawings. The same reference numbers in different drawings may identify the same or similar elements.

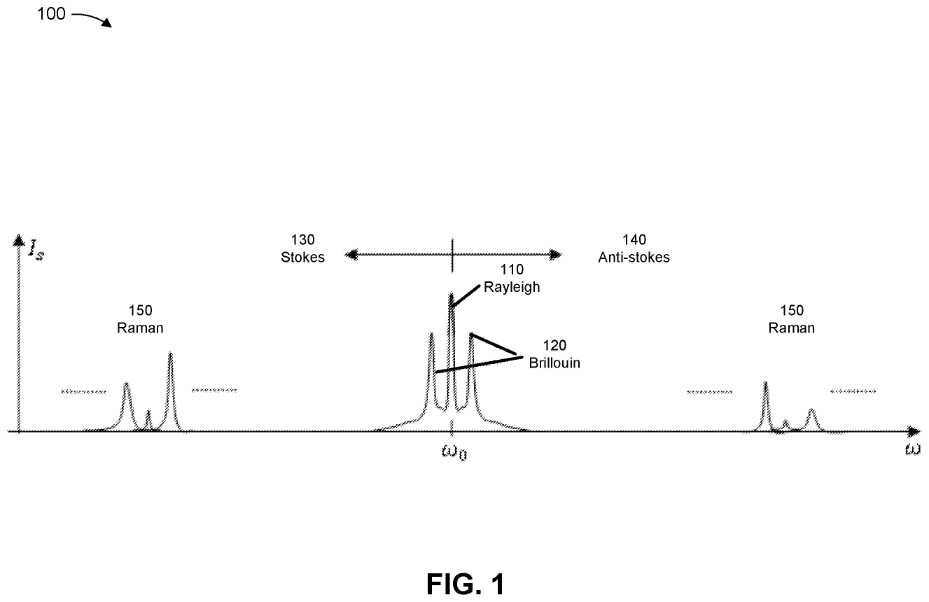

FIG. 1 is a diagram illustrating an example 100 of light scattering. For example, when a light wave propagates in a medium, such as an optical fiber, the light wave interacts with constituent atoms and molecules within the medium and creates an electric field. In cases where the light wave has a wavelength that is far from a medium resonance, the electric field induces a time-dependent polarization dipole that generates a secondary electromagnetic wave, which is generally referred to as light scattering. Because the distances between scattering centers (particles) are smaller than the wavelength of light in the optical fiber, the secondary light waves are coherent for Rayleigh scattering. When the medium is perfectly homogeneous, the phase relationship of the emitted waves allows only the forward scattered beam to propagate. However, optical fibers are inhomogeneous mediums, where scattering arises from microscopic or macroscopic variations in density, composition, or structure of a material through which light is passing. The random ordering of the molecules and the presence of dopants causes localized variations in density (and therefore refractive index), which causes Rayleigh scattering that attenuates the forward-propagating signal and creates a backward-propagating signal.

For example, in FIG. 1, reference number 110 depicts a Rayleigh scattering peak, where Rayleigh scattering is a linear scattering process in that the scattered power is proportional to an incident power. Furthermore, no energy is transferred to the glass in Rayleigh scattering, which is elastic scattering in that the scattered light does not exhibit a change in frequency compared with the incident light. Instead, Rayleigh scattering is attributed to non-propagating density fluctuations. As further shown in FIG. 1, reference number 120 depicts Brillouin lines that appear on both sides of the Rayleigh peak, where the Brillouin lines are created by the scattering of sound waves moving in opposite directions. As further shown in FIG. 1, reference number 130 depicts a Stokes line with a down-shifted frequency to the left of the Rayleigh peak, while reference number 140 depicts an anti-Stokes line with an up-shifted frequency to the right of the Rayleigh peak. As shown by reference number 150, Raman lines are formed by the interaction of the light wave with molecular vibrations in the medium. Brillouin and Raman scattering are inelastic scattering because Brillouin and Raman scattering are associated with frequency shifts.

As shown in FIG. 1, Raman spectra usually contain several sharp bands with separations between bands. The separation between bands generally corresponds to electronic vibrations, and each bandwidth results from molecular rotation or reorientation excitations. In cases where the input light is scattered without strongly altering the optical properties of the medium, the scattering is spontaneous, which includes Rayleigh, Brillouin, and Raman scattering. When the light intensity increases to a level such that the optical properties of the medium are modified, and the scattered light is proportional to the power of the input light, the scattering regime becomes stimulated. In other words, the transition from spontaneous to stimulated scattering corresponds to a transition of the medium behavior from a linear to a nonlinear regime.

FIG. 1 is provided as an example. Other examples may differ from what is described with regard to FIG. 1.

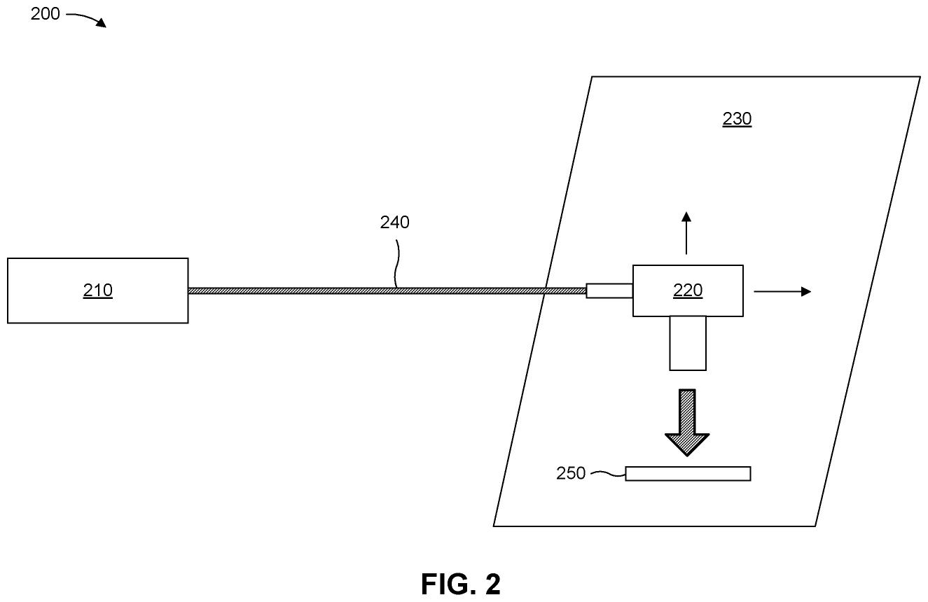

FIG. 2 is a diagram illustrating an example industrial beam delivery system 200, which may be used in applications such as laser material processing. For example, laser material processing has many advantages, including high productivity, a non-contact nature of material processing, improved quality, and high precision and mobility of a laser beam delivery point. Lasers are used in various industrial applications, including cutting, drilling, welding, brazing, surface annealing, alloying, and/or hardening, among other examples. For example, in an industrial laser application, a beam delivery system often includes an optical fiber used to deliver a high-power and/or a high-intensity laser beam to a target.

For example, as shown in FIG. 2, an industrial beam delivery system 200 may include a fiber laser engine 210 (e.g., a multi-kilowatt (kW) fiber laser engine) that may be connected to a process head 220 in an application area 230 (e.g., a cutting and/or welding area) through a process cable 240 that typically has a length in a range from approximately 5 to 50 meters (m). The process cable 240 may be provided in a reinforced cable that is pluggable on an input end and an output end, and the process head 220 is an optical assembly that includes a receptacle to receive the input end of process cable 240, optics to project laser power, and any laser-based processing accessories that may be needed, such as assist-gas ports. The fiber laser engine 210 may transmit a laser into an optical coupler unit, either through free space or through a separate optical fiber, and the optical coupler unit may launch the laser into the process cable 240. Accordingly, the process cable 240 generally transmits the laser to the process head 220, which may then project the laser onto a workpiece 250 disposed in the application area 230 in order to perform a desired laser material processing task (e.g., cutting, drilling, welding, or the like). For example, the process head 220 may include free space optics that focus the laser light onto the workpiece 250 for the desired laser material processing task.

As described herein, the fiber laser engine 210 in an industrial fiber laser system is typically a kW laser source that may provide laser light with a power in a range from approximately 10 to 50 kW. In a typical configuration, the fiber laser engine 210 is associated with a single wavelength in a range from approximately 1030 to 1090 nanometers (nm). The process cable 240 is used to deliver laser light from the laser engine 210 to the process head 220, and typically has a long length (e.g., at least 5 m) and a diameter that increases with power (e.g., from 50 to 500 micrometers (μm), or microns). For example, the process cable 240 has a long length because the process head 220 is typically accelerating quickly in a large machine, and the weight of the fiber laser engine 210 cannot burden a gantry that moves the process head 220 within the application area 230 to direct the laser toward material to be cut, welded, engraved, and/or otherwise processed (e.g., a movable beam delivery system allows the laser to be moved within the application area 230 without having to move the fiber laser engine 210, which may be very heavy). Furthermore, the long length of the process cable 240 may be advantageous in that the fiber laser engine 210 can be placed in a well-protected area with good access for service operations, rather than placing the fiber laser engine 210 close to the application area 230.

However, the long length of the process cable 240 may pose various challenges, including optical power losses, pulse broadening, and/or nonlinear limitations. For example, higher laser power generally leads to faster material processing, which creates a demand for higher and higher laser powers in industrial applications (e.g., currently between 15-20 kW). As the laser power increases, however, delivering laser light with a high brightness and a high power through tens of meters of optical fiber becomes increasingly challenging due to problematic nonlinear effects such as stimulated Raman scattering (SRS). For example, as laser power increases, SRS begins to dominate for continuous wave (CW) industrial fiber lasers or quasi-CW kW fiber lasers often used in cutting and welding industries. In particular, SRS is a nonlinear optical effect where energy from an optical pump beam is converted to a longer wavelength via vibrational and/or rotational modes or phonons being excited in the molecules of a glass medium. While this may be useful for certain applications (e.g., to turn an optical fiber into a Raman amplifier or a tunable Raman laser, or for distributed fiber optic sensors), SRS is undesirable for multi-kW CW industrial fiber lasers or quasi-CW kW fiber lasers used in cutting, welding, and/or other industrial applications. For example, in industrial applications, SRS may transfer energy from one channel to a neighboring channel and/or limit the power that can propagate without unwanted loss and/or heating, which may negatively impact the industrial processes and/or cause damage to equipment. Accordingly, as power levels for industrial kW fiber lasers increase, SRS becomes more problematic, and a need arises for SRS suppression techniques. However, existing techniques to avoid SRS and other nonlinear effects are typically limited to increasing a diameter of the process cable 240, which significantly degrades laser brightness and complicates optics of the process head 220. Furthermore, although spectral beam combining can theoretically achieve high brightness, spectral beam combining needs to be done in free space, does not power scale, and lacks stability.

FIG. 2 is provided as an example. Other examples may differ from what is described with regard to FIG. 2. The number and arrangement of devices shown in FIG. 2 are provided as examples. In practice, there may be additional devices, fewer devices, different devices, or differently arranged devices than those shown in FIG. 2. Furthermore, two or more devices shown in FIG. 2 may be implemented within a single device, or a single device shown in FIG. 2 may be implemented as multiple, distributed devices. Additionally, or alternatively, a set of devices (e.g., one or more devices) shown in FIG. 2 may perform one or more functions described as being performed by another set of devices shown in FIG. 2.

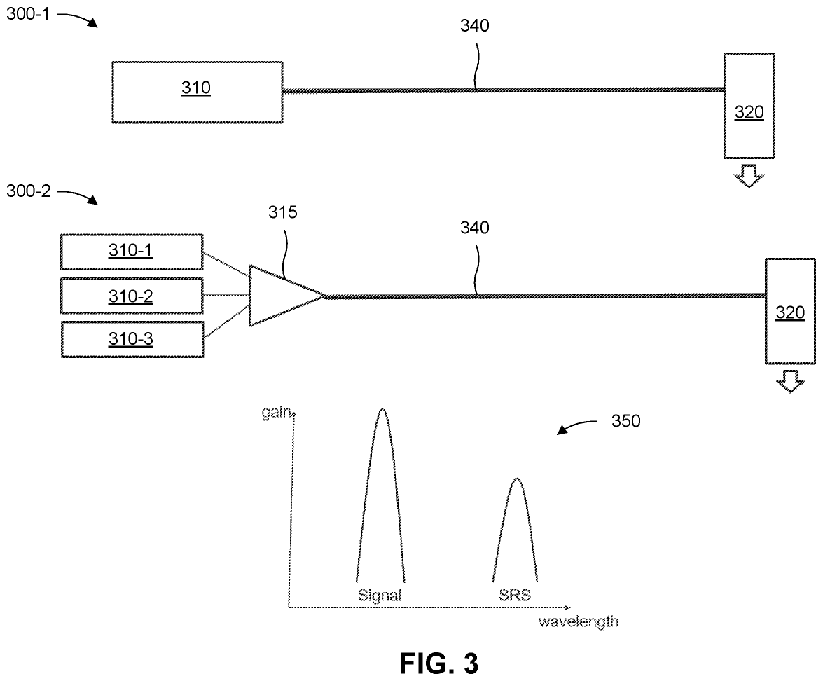

FIG. 3 is a diagram illustrating examples 200-1 and 200-2 of single-wavelength fiber laser systems. In general, examples 200-1 and 200-2 are illustrative of typical or standard industrial fiber laser configurations, where a fiber laser engine 310 is associated with a single wavelength in a range from approximately 1030 to 1090 nm and a process cable 340 with a long length (e.g., at least 5 m) and a diameter that increases with power (e.g., from 50 to 500 μm, or microns) is used to deliver laser light from the laser engine 310 to a process head 320. As described herein, examples 300-1 and 300-2 relate to single-wavelength fiber laser systems that may be used to transmit a laser associated with a kW power level at suitable wavelength (e.g., in between 1030-1090 nm) using a process cable 340 with a diameter between 50 to 500 μm and a length that exceeds 5 m. For example, in one illustrative configuration described herein, examples 300-1 and 300-2 may be used to transmit a 30 kW laser at a 1070 nm wavelength using a process cable 340 with a 100 μm diameter and a 20 m length.

As shown by example 300-1, the laser can be generated using a single module fiber laser engine 310 (e.g., a single module to generate a 30 kW laser at 1070 nm). Alternatively, the laser can be generated by combining multiple fiber laser engines. For example, in FIG. 3, example 300-2 depicts a configuration in which three fiber laser engines 310-1, 310-2, 310-3 each generate a laser at the same wavelength (e.g., respective 10 kW lasers at 1070 nm), which are then combined using a 3:1 combiner 315. However, because SRS scales as a function of power divided by an effective area, the SRS is additive in examples 300-1 and 300-2 because the laser(s) delivered through the process cable 340 are all at a single wavelength. For example, in configurations where a 30 kW laser is delivered at 1070 nm, the SRS gain is approximately 33 decibels (dB) through a process cable 340 with a 20 m length. For example, reference number 350 depicts an example plot of the SRS gain as a function of wavelength, where using a single laser or incoherently combining multiple single wavelength lasers leads to a narrowband laser source that suffers from having a low SRS threshold. For example, an SRS threshold generally refers to the minimum intensity or power of incident laser light that is needed to initiate significant SRS in the process cable 340. Below the SRS threshold, nonlinear effects are typically weak, and the SRS process is not pronounced. However, above the SRS threshold, as the intensity or power of the incident light increases, the SRS process becomes more efficient, and the Raman-shifted photons becomes more prominent. Accordingly, a relatively low SRS threshold may result in deleterious SRS effects at lower power levels. One common solution to this problem is to increase the diameter of the process cable 340 (e.g., from 100 μm to 200 μm) and deliver the laser with a decreased brightness. Other suboptimal solutions include shortening the process cable 340 or stripping out the SRS with a filter at the output.

Accordingly, some implementations described herein relate to a multi-wavelength laser for kW material processing. For example, in some implementations, an all-fiber, high-power broadband laser may combine multiple wavelength fiber lasers incoherently with a fused fiber signal combiner in order to deliver a broad spectrum, high-brightness laser for material processing while avoiding nonlinear effects such as SRS. In this way, power scaling may be achieved by adding multiple wavelength lasers, which allows the process cable to have a smaller core diameter, thereby preserving brightness and avoiding nonlinear effects such as SRS.

FIG. 3 is provided as an example. Other examples may differ from what is described with regard to FIG. 3. The number and arrangement of devices shown in FIG. 3 are provided as examples. In practice, there may be additional devices, fewer devices, different devices, or differently arranged devices than those shown in FIG. 3. Furthermore, two or more devices shown in FIG. 3 may be implemented within a single device, or a single device shown in FIG. 3 may be implemented as multiple, distributed devices. Additionally, or alternatively, a set of devices (e.g., one or more devices) shown in FIG. 3 may perform one or more functions described as being performed by another set of devices shown in FIG. 3.

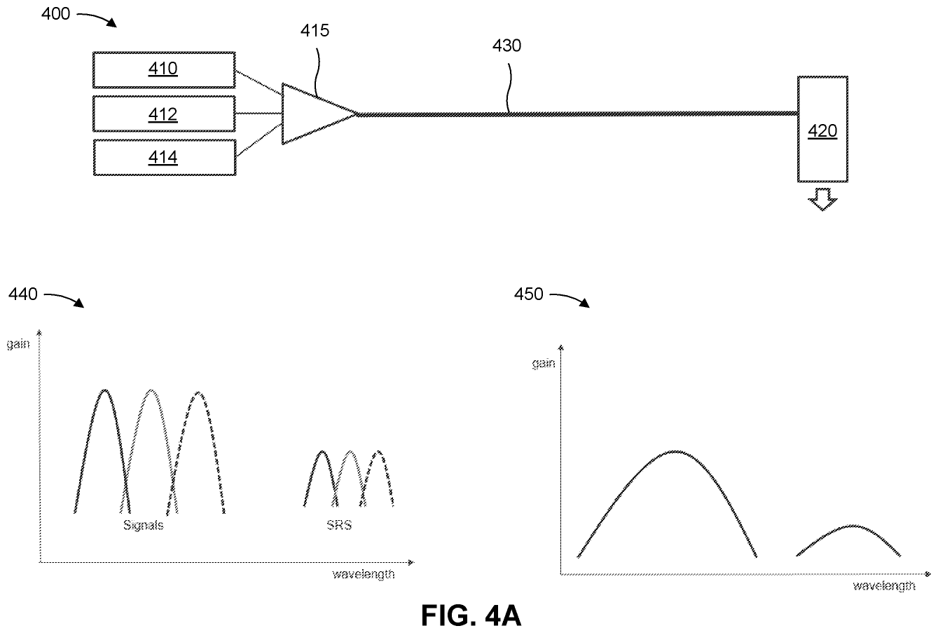

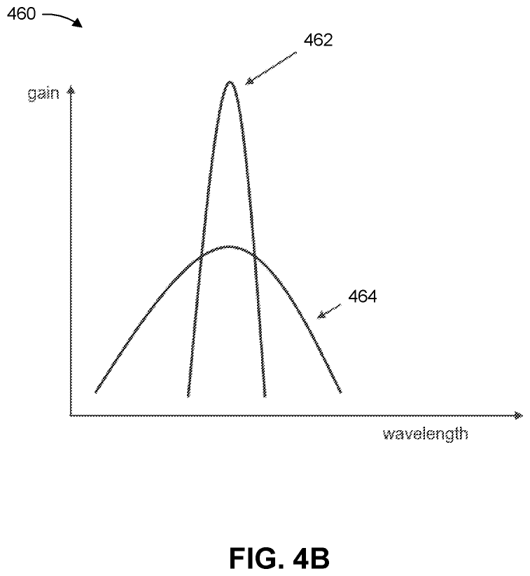

FIGS. 4A-4B are diagrams illustrating an example multi-wavelength fiber laser system 400 that may be used for kW material processing or other suitable applications. For example, as shown in FIG. 4A, the multi-wavelength laser comprises multiple fiber laser sources 410, 412, 414 that are connected to a process head 420 through a process cable 430, where the multiple fiber laser sources 410, 412, 414 each operate at a different wavelength. For example, in one configuration, a 30 kW multi-wavelength solution may be achieved using a first fiber laser source 410 that generates a 10 KW laser at a first wavelength (e.g., 1080 nm), a second fiber laser source 412 that generates a 10 KW laser at a second wavelength (e.g., 1075 nm), and a third fiber laser source 414 that generates a 10 kW laser at a third wavelength (e.g., 1070 nm). In general, however, the laser engine may include two or more laser sources that generate respective lasers that are associated with different wavelengths, where the two or more laser source may operate at the same power level or at different power levels. Furthermore, in some implementations, the lasers associated with the different wavelengths are incoherently combined with a fused fiber signal combiner 415, which delivers the incoherently combined lasers into the process cable 430. In a configuration where the process cable 430 has a core diameter of 100 μm and a length of 20 m, the SRS gain is approximately 11 dB for each laser wavelength, which is a net 3× reduction in the SRS gain for the same effective diameter and length of the process cable 430 relative to a single laser or incoherently combining multiple single wavelength lasers.

Accordingly, as shown in FIG. 4A, the multi-wavelength fiber laser system 400 includes a laser engine with multiple laser sources (e.g., laser sources 410, 412, 414), where the multiple laser sources are configured to generate multiple lasers associated with different wavelengths. In addition, the laser engine includes the signal combiner 415 to receive the multiple lasers associated with the different wavelengths and to combine the multiple lasers into broadband laser light that is transmitted through the process cable 430 to a process head 420 that receives the broadband laser light and focuses the broadband laser light onto a workpiece (not shown in FIG. 4A). Furthermore, as described herein, the signal combiner 415 is configured to incoherently combine the multiple lasers associated with the different wavelengths, whereby the multiple laser sources and the signal combiner 415 are equivalent to a broadband signal source that increases the SRS threshold (e.g., increasing the minimum intensity or power of incident laser light that results in significant SRS in the process cable 430). Furthermore, in some cases, the multiple lasers that are generated by the multiple laser sources may be provided at equal power levels (e.g., 10 kW for the multiple fiber laser sources 410, 412, 414 in examples described herein). Additionally, or alternatively, in some cases, the multiple lasers generated by the multiple laser sources may be associated with at least two different power levels. For example, different power levels may be used for different lasers, which allows lower powers to be used for lower wavelengths and higher powers to be used for lower wavelengths to further reduce SRS. In addition, the multiple lasers may be associated with a uniform spacing between the different wavelengths (e.g., the laser sources 410, 412, 414 may generate respective lasers at 1080 nm, 1075 nm, and 1070 nm, providing a 5 nm spacing between lasers). In some implementations, the exact spacing between the wavelengths of the multiple laser sources may vary depending on various factors, such as the number of lasers that are being combined by the combiner 415.

Accordingly, because SRS generally scales as a function of power over effective area, individual signal wavelengths that have little to no overlap can be handled separately with respect to SRS gain, which allows the laser to be delivered to the process head 420 at a high power and with a high brightness. For example, in FIG. 4A, reference number 440 depicts a plot of the SRS gain as a function of wavelength, where the individual signal wavelengths that are generated by the different fiber laser sources 410, 412, 414 have minimal overlap, which results in a distinct SRS gain per signal wavelength. Furthermore, in FIG. 4A, reference number 450 depicts a plot that is equivalent to the plot depicted by reference number 440, where multiple incoherently combined lasers that are associated with different wavelengths are equivalent to a broadband signal source, which increases the SRS threshold. In this way, because the multiple lasers are associated with different wavelengths, the multiple lasers are associated with respective SRS gains that are distributed over the different wavelengths. In other words, the SRS gain can be treated separately over the different wavelengths, relative to a single laser or multiple laser sources operating at the same wavelength, where the SRS gain is additive.

For example, referring to FIG. 4B, reference number 460 depicts a comparison between the SRS gain experienced in a single wavelength fiber laser engine and a multi-wavelength fiber engine. For example, curve 462 depicts the SRS gain experienced in a single wavelength fiber laser engine (e.g., as depicted in FIG. 3) and curve 464 depicts the SRS gain experienced in a multi-wavelength fiber laser engine (e.g., as depicted in FIG. 4A). As shown, the multi-wavelength fiber laser engine exhibits a lower SRS gain than the single wavelength fiber laser engine. In particular, the signal combiner 415 in the multi-wavelength fiber laser system 400 is configured to combine the multiple lasers associated with the different wavelengths to generate a broadband signal that is distributed over a range associated with the different wavelengths, which results in an SRS gain that is less than individual SRS gains associated with the multiple lasers. In this way, the multi-wavelength fiber laser system 400 offers various advantages, such as allowing the process cable 430 to have a smaller core diameter at kW power levels, which helps to preserve brightness and avoid nonlinear effects such as SRS. For example, in some implementations, the multi-wavelength fiber laser system 400 may be used to effectively scale power in cases where the process cable 430 has a core diameter of 100 μm or less and/or in cases where the broadband laser light transmitted through the process cable 430 has a power of at least 10 kW. However, it will be appreciated that using multiple laser sources that generate respective lasers at different wavelengths and incoherently combining the respective lasers may be suitable for any laser application where there is a need to suppress SRS or other nonlinear effects without having to compromise brightness (e.g., by increasing the core diameter of the process cable 430), shorten the process cable 430 (e.g., creating challenges in applications where a long length is needed for the process cable 430), and/or increase cost or complexity by deploying a filter to strip out the SRS at the output from the process cable 430.

FIGS. 4A-4B are provided as examples. Other examples may differ from what is described with regard to FIGS. 4A-4B. The number and arrangement of devices shown in FIGS. 4A-4B are provided as examples. In practice, there may be additional devices, fewer devices, different devices, or differently arranged devices than those shown in FIGS. 4A-4B. Furthermore, two or more devices shown in FIGS. 4A-4B may be implemented within a single device, or a single device shown in FIGS. 4A-4B may be implemented as multiple, distributed devices. Additionally, or alternatively, a set of devices (e.g., one or more devices) shown in FIGS. 4A-4B may perform one or more functions described as being performed by another set of devices shown in FIGS. 4A-4B.

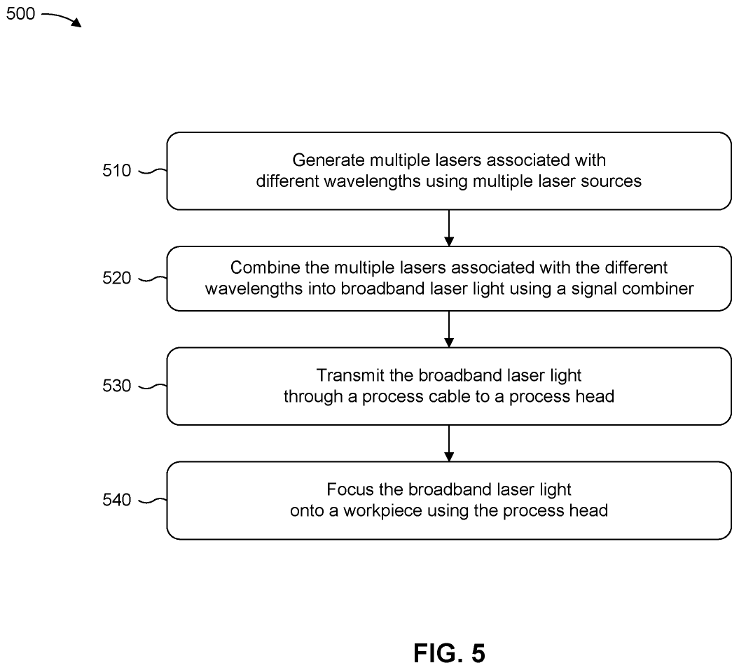

FIG. 5 is a flowchart of an example process 500 associated with kW laser material processing using a multi-wavelength laser. In some implementations, one or more process blocks of FIG. 5 are performed by an optical system (e.g., multi-wavelength fiber laser system 400).

As shown in FIG. 5, process 500 may include generating multiple lasers associated with different wavelengths using multiple laser sources (block 510). For example, the multi-wavelength fiber laser system 400 may generate multiple lasers associated with different wavelengths using multiple laser sources 410, 412, 414, as described above.

As further shown in FIG. 5, process 500 may include combining the multiple lasers associated with the different wavelengths into broadband laser light using a signal combiner (block 520). For example, the multi-wavelength fiber laser system 400 may combine the multiple lasers associated with the different wavelengths into broadband laser light using a signal combiner 415, as described above.

As further shown in FIG. 5, process 500 may include transmitting the broadband laser light through a process cable to a process head (block 530). For example, the multi-wavelength fiber laser system 400 may transmit the broadband laser light through a process cable 430 to a process head 420, as described above.

As further shown in FIG. 5, process 500 may include focusing the broadband laser light onto a workpiece using the process head (block 540). For example, the multi-wavelength fiber laser system 400 may focus the broadband laser light onto a workpiece using the process head 420, as described above.

Process 500 may include additional implementations, such as any single implementation or any combination of implementations described below and/or in connection with one or more other processes described elsewhere herein.

In a first implementation, the process cable 430 has a core diameter of 100 microns or less and the broadband laser light has a power of at least ten kW.

In a second implementation, alone or in combination with the first implementation, the signal combiner 415 is configured to incoherently combine the multiple lasers associated with the different wavelengths.

In a third implementation, alone or in combination with one or more of the first and second implementations, the multiple lasers are associated with respective SRS gains that are distributed over the different wavelengths.

In a fourth implementation, alone or in combination with one or more of the first through third implementations, the broadband laser light is distributed over a range associated with the different wavelengths and has a gain that is less than individual gains associated with the multiple lasers.

Although FIG. 5 shows example blocks of process 500, in some implementations, process 500 includes additional blocks, fewer blocks, different blocks, or differently arranged blocks than those depicted in FIG. 5. Additionally, or alternatively, two or more of the blocks of process 500 may be performed in parallel.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

When a component or one or more components (e.g., a laser emitter or one or more laser emitters) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”).

What is claimed is:

1. A laser engine, comprising:
multiple laser sources that are configured to generate multiple lasers associated with different wavelengths; and
a signal combiner configured to:
receive the multiple lasers associated with the different wavelengths; and
combine the multiple lasers associated with the different wavelengths.

2. The laser engine of claim 1, wherein the signal combiner is configured to incoherently combine the multiple lasers associated with the different wavelengths.

3. The laser engine of claim 1, wherein the multiple lasers generated by the multiple laser sources are associated with equal power levels.

4. The laser engine of claim 1, wherein the multiple lasers generated by the multiple laser sources are associated with at least two different power levels.

5. The laser engine of claim 1, wherein the multiple lasers are associated with a uniform spacing between the different wavelengths.

6. The laser engine of claim 1, wherein the multiple lasers are associated with respective stimulated Raman scattering (SRS) gains that are distributed over the different wavelengths.

7. The laser engine of claim 1, wherein the signal combiner is configured to combine the multiple lasers associated with the different wavelengths to generate a broadband signal that is distributed over a range associated with the different wavelengths and has a gain that is less than individual gains associated with the multiple lasers.

8. An optical system, comprising:
multiple laser sources that are configured to generate multiple lasers associated with different wavelengths;
a signal combiner configured to combine the multiple lasers associated with the different wavelengths into broadband laser light;
a process cable configured to transmit the broadband laser light; and
a process head configured to receive the broadband laser light transmitted by the process cable and to focus the broadband laser light onto a workpiece.

9. The optical system of claim 8, wherein the process cable has a core diameter of one hundred microns or less and the broadband laser light has a power of at least ten kilowatts.

10. The optical system of claim 8, wherein the signal combiner is configured to incoherently combine the multiple lasers associated with the different wavelengths.

11. The optical system of claim 8, wherein the multiple lasers generated by the multiple laser sources are associated with equal power levels.

12. The optical system of claim 8, wherein the multiple lasers generated by the multiple laser sources are associated with at least two different power levels.

13. The optical system of claim 8, wherein the multiple lasers are associated with a uniform spacing between the different wavelengths.

14. The optical system of claim 8, wherein the multiple lasers are associated with respective stimulated Raman scattering (SRS) gains that are distributed over the different wavelengths.

15. The optical system of claim 8, wherein the broadband laser light is distributed over a range associated with the different wavelengths and has a gain that is less than individual gains associated with the multiple lasers.

16. A method for laser material processing, comprising:
generating, by an optical system, multiple lasers associated with different wavelengths using multiple laser sources;
combining, by the optical system, the multiple lasers associated with the different wavelengths into broadband laser light using a signal combiner;
transmitting, by the optical system, the broadband laser light through a process cable to a process head; and
focusing, by the optical system, the broadband laser light onto a workpiece using the process head.

17. The method of claim 16, wherein the process cable has a core diameter of one hundred microns or less and the broadband laser light has a power of at least ten kilowatts.

18. The method of claim 16, wherein the signal combiner is configured to incoherently combine the multiple lasers associated with the different wavelengths.

19. The method of claim 16, wherein the multiple lasers are associated with respective stimulated Raman scattering (SRS) gains that are distributed over the different wavelengths.

20. The method of claim 16, wherein the broadband laser light is distributed over a range associated with the different wavelengths and has a gain that is less than individual gains associated with the multiple lasers.
